(19) United States
(12) Patent Application Publication
(10) Pub. No.: US 2014/0015614 A1
(43) Pub. Date: Jan. 16, 2014

(54) System and Method for a Low Noise Amplifier

(71) Applicants: Paulo Oliveira, Neubiberg (DE); Daniel Kehrer, Sauerlach (DE)

(72) Inventors: Paulo Oliveira, Neubiberg (DE); Daniel Kehrer, Sauerlach (DE)

(73) Assignee: INFINEON TECHNOLOGIES AG, Neubiberg (DE)

(21) Appl. No.: 13/545,732

(22) Filed: Jul. 10, 2012

(51) Int. Cl. H03F 3/14

(52) U.S. Cl. 330/307

(57) ABSTRACT

In accordance with an embodiment, a low noise amplifier (LNA) includes a transistor, and a transformer having a first winding coupled between a LNA input terminal and a control node of the transistor, and a second winding magnetically coupled to the first winding coupled between a reference node of the transistor and a LNA reference terminal. An output of the LNA is coupled to an output node of the transistor.

### TECHNICAL FIELD

This invention relates generally to semiconductor circuits and methods, and more particularly to a system and method for a low noise amplifier.

### BACKGROUND

Electronic devices used with wireless communication systems, such as cellular phones, GPS receivers, and Wi-Fi enabled notebook and tablet computers, generally contain signal processing systems that have interfaces to the analog world. Such interfaces may include wire line and wireless receivers that receive transmitted power and convert the received power to an analog or digital signal that may be demodulated using analog or digital signal processing techniques. A typical wireless receiver architecture includes a low noise amplifier (LNA) that amplifies the very small signals that may be received by an antenna, provides gain to these small signals and passes an amplified signal to later amplification and/or signal processing stages. By providing gain at the LNA, subsequent gain processing stages are made insensitive to noise, thereby enabling a lower system noise figure.

An LNA circuit generally contains at least one transistor and an input matching network. The purpose of the input matching network, which may be made of one or more passive devices such as inductors and capacitors, is to provide an impedance match and/or a noise match to a previous stage, such as an antenna, a filter, an RF switch, or other circuit. LNA implementations may also include an output matching network, a bias network, and other circuit structures such as a cascode transistor.

As wireless RF devices are becoming smaller and more power efficient, the physical size of the matching devices and other passive circuit structure, which are typically implemented using surface mount devices on the circuit board, may begin to comprise a large portion of the surface area of the LNA. In some cases, portions of the matching network may be included on the same piece of silicon and as the LNA transistor. If the on-chip matching network includes an inductor, such as a bias inductor, matching inductor, a choke inductor, the physical size of the integrated inductors may take up a significant percentage of the die area of the LNA integrated circuit.

### SUMMARY OF THE INVENTION

In accordance with an embodiment, a low noise amplifier (LNA) includes a transistor, and a transformer having a first winding coupled between a LNA input terminal and a control node of the transistor, and a second winding magnetically coupled to the first winding coupled between a reference node of the transistor and a LNA reference terminal. An output of the LNA is coupled to an output node of the transistor.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an LNA according to the prior art;

FIGS. 2a-c illustrates embodiment LNA integrated circuits using bipolar transistors and a spiral inductor based transformer;

FIGS. 3a-b illustrate embodiment MOS based LNA integrated circuits;

FIG. 4 illustrates an embodiment LNA circuit according to a further embodiment;

FIG. 5 illustrates a physical layout implementation of an embodiment LNA integrated circuit;

FIG. 6 illustrates a block diagram of an embodiment RF signal path that uses an embodiment LNA;

FIGS. 7a-b illustrate an embodiment LNA within a shielded package;

FIG. 8 illustrates a block diagram of a conventional shielded LNA; and

FIG. 9 illustrates a block diagram of an embodiment shielded LNA.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to embodiments in a specific context, namely a low noise amplifier. Embodiments of the present invention are not limited to low noise amplifiers, and may also be applied to other types of amplifiers, as well as other types of circuits.

In an embodiment, an LNA contains a transistor and a transformer disposed on a same substrate. A first winding of the transformer is coupled between an input port of the LNA and a control node of the transistor, and a second winding of the transformer is coupled between a reference node of the transistor and a reference port of the LNA. In some embodiments, the transistor is a BJT transistor, such that the control node is a base of the BJT and the reference node is an emitter of the BJT. In other embodiments, the transistor may be implemented using a MOSFET, such as an NMOS transistor. Here, the control node may be the gate of the MOSFET transistor and the reference node may be the source of the MOSFET transistor. Accordingly, in some embodiments, an area-efficient monolithic LNA may be formed that has an accurate input-port power match with a low noise figure.

During the design of an LNA circuit, four objectives or specifications may be taken into account, namely, power gain, noise, matching and linearity. These four objectives may be conflicting. For example, if one improves the noise performance of a device, there may be a trade-off with respect to linearity, matching and power gain. In one respect, a designer may want to ensure that an LNA has an adequate power gain in order to increase the signal power passed on to subsequent stages. By increasing the gain in the LNA, the noise contribution of later stages is reduced; and by making the noise figure of the LNA low enough, adequate sensitivity to small input powers may be achieved. For example, in a GPS system, the minimum detectable signal level, which is received from an orbiting satellite, may be as low as about −128 dBm. Accordingly, input and output matching networks may be used to maximize power transfer and to provide termination for front-end filters. Lastly, the LNA may be designed to have enough linearity to reduce the effect of intermodulation between competing signals.

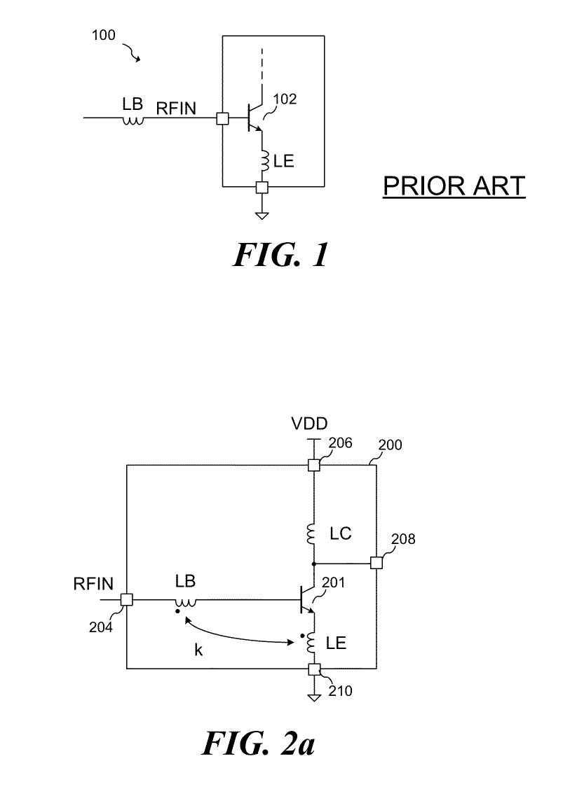

Among traditional RF amplifier topologies, the inductively degenerated common-emitter stage stands out for its ability to simultaneously realize a minimum noise figure and provide input impedance matching. An example of such a topology is illustrated in FIG. 1 as LNA 100, which has transistor 102 coupled to input inductor LB at its base, and degeneration inductor LE coupled to its emitter. In this topology, the optimum noise resistance and device input resistance may be adjusted independently, as described in Sorin P. Voinigescu et al., “A Scalable High-Frequency Noise Model for Bipolar Transistors with Application to Optimal Transistor Sizing for Low-Noise Amplifier Design”, IEEE Journal of Solid-State Circuits, Vol. 32, No. 9, September 1997, which has been incorporated by reference herein in its entirety.

By changing the size and biasing conditions of the LNA's input transistor, the optimum noise resistance may be set to a particular resistance, for example 50Ω. The device's input resistance is then raised to 50Ω by applying inductive emitter degeneration (LE). To complete the power match, a few times larger inductance (LB) may be needed at the input of the amplifier. Inductance LB is typically implemented as an external SMD on board.

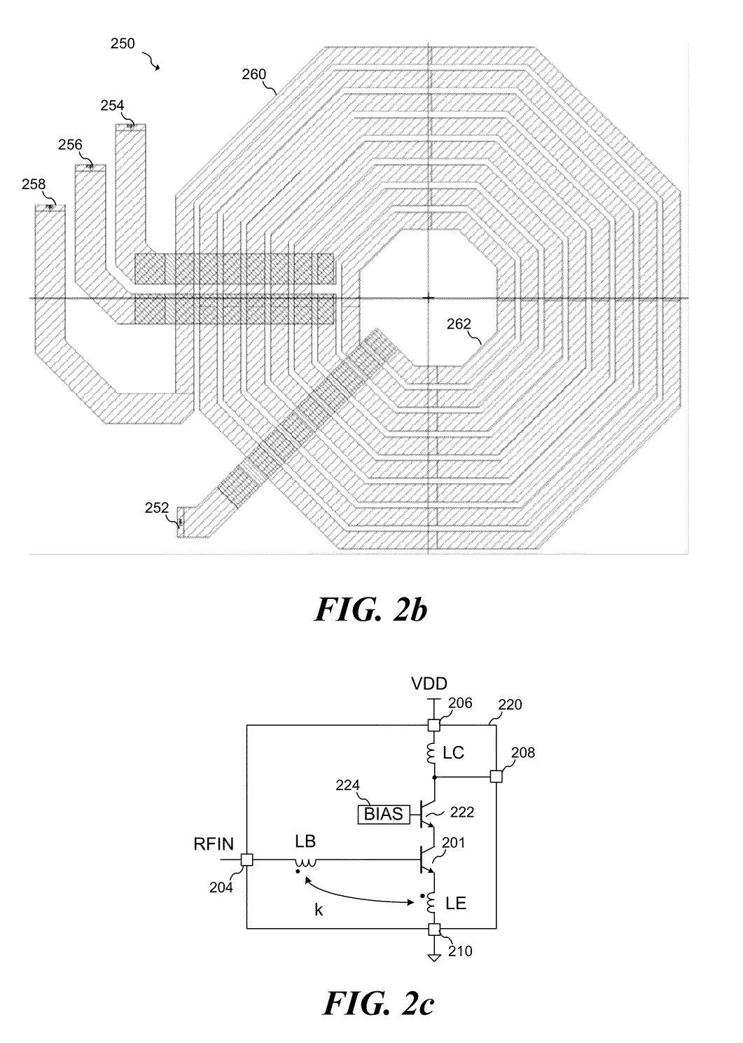

FIG. 2a illustrates LNA integrated circuit 200 according to an embodiment of the present invention. Integrated circuit 200 has transistor 201; input inductor LB coupled between RF input pin 204 and the base of transistor 201; emitter degeneration inductor LE coupled between the emitter of transistor 201 and reference pin 210; and output inductor LC coupled between the collector of transistor 201 and power supply pin 206. In an embodiment, inductor LB is transformer coupled to inductor LE, and RF output pin 208 is coupled to the collector of transistor 201. In some embodiments, RF output pin may be coupled to further components, such as an output matching network. In some cases, inductor LB and inductor LE may be implemented as spiral inductors. These inductors may be further implemented on a same metallization layer, or on different metallization layers. Alternatively, other inductor types may be used.

In one embodiment, integrated circuit 200 is implemented on a silicon germanium (SiGe) process having at least one copper metal layer. In processes that have a single copper metal layer, inductors LB and LE may be implemented using a spiral inductor in which one winding of the transformer may include an inner portion of the spiral, and another winding of the transformer may include an outer portion of the spiral as shown in FIG. 2b, which illustrates spiral inductor based transformer 250. In an embodiment, transformer has outer spiral inductor 260 having terminals 256 and 258, and inner spiral inductor 262 having terminals 252 and 254. It should be understood that the transformer 250 is just one of many examples of embodiment transformers. Other structures and geometries having, for example, other turns ratios may be used. It should be understood that spiral inductor based transformer 250 may also be used in conjunction other embodiments described herein.

In alternative embodiments of the present invention, two or more metallization layers may be used instead of a single metallization layer to implement this transformer. The choice of how to implement the transformer may depend on the quality of the available process, the types of Qs that are achievable within the available process, and the requirements of the particular LNA being implemented. It should be further appreciated that other semiconductor processes may be used besides a SiGe process.

In an embodiment, LNA integrated circuit 200 may be included in the RF front-end of a GPS receiver, a UMTS receiver, or other receiver that supports one or more various telecommunications and/or navigation standards. In one embodiment, LNA integrated circuit 200 may be used to implement an LNA that achieves, for example, a gain of between about 17 dB and about 20 dB, a noise figure of about 1 dB, and an in-band IP3 of about 0 dBm. In alternative embodiments of the present invention, other specifications and/or performance metrics may be achieved. Moreover, LNA integrated circuit 200 may be implemented using flip chip technologies having a very small bonding inductance, however, other packaging technologies may be used, such as those that may require the use of bond wires. When bond wires are used, the electrical performance and inductance of the bond wires may be taken into account during the design of the integrated circuit.

In an embodiment, the transformer may be configured to increase or maximize inductive coupling k between the two windings that form LB and LE. As such, the layout of the transformer may be more compact when compared to a circuit using two separate uncoupled coils. Furthermore, the overall quality factor Q of inductances LB and LE may be increased with respect to an uncoupled implementation, which may further improve noise performance.

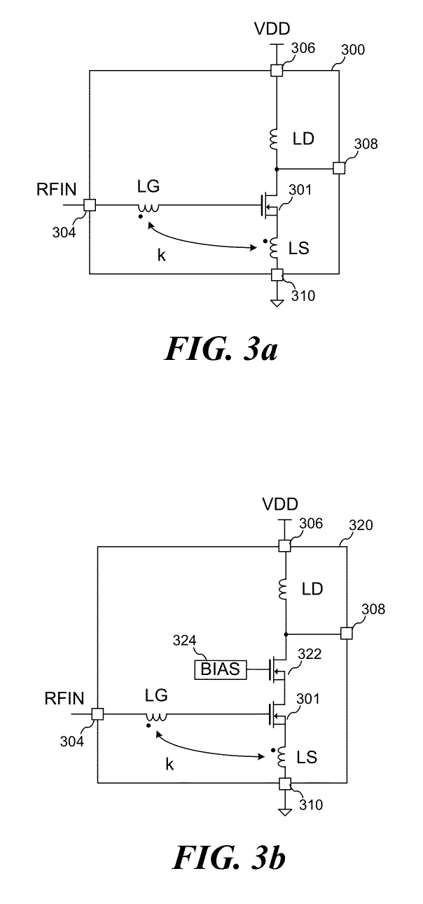

FIG. 2c illustrates LNA integrated circuit 220 according to an alternative embodiment of the present invention. LNA integrated circuit 220 is similar to LNA integrated circuit 200 with the addition of cascode transistor 222 biased with bias generator 224. Bias generator 224 may be implemented using bias generation techniques known in the art. Transistors 201 and/or transistor 222 may be implemented using other types of transconductance devices. For example, an embodiment LNA may be implemented using MOSFET transistor 301, as illustrated in FIG. 3a. In an embodiment, integrated circuit 300 has MOSFET transistor 301; input inductor LG coupled between RF input pin 304 and the gate of transistor 301; source degeneration inductor LS coupled between the source of transistor 301 and reference pin 310; and output inductor LD coupled between the drain of transistor 301 and power supply pin 306. RF output pin 308 may be coupled to the drain of transistor 301. In an embodiment, inductor LG is transformer coupled to inductor LS. Moreover, inductors LB and LE may be implemented as spiral inductors or as other inductor types. These inductors may be implemented on a same metallization layer, or on different metallization layers.

FIG. 3b illustrates MOSFET based LNA integrated circuit 320 according to an alternative embodiment. LNA integrated circuit 320 is similar to LNA integrated circuit 300 with the addition of cascode transistor 322 biased with bias generator 324. Bias generator 324 may be implemented using bias generation techniques known in the art.

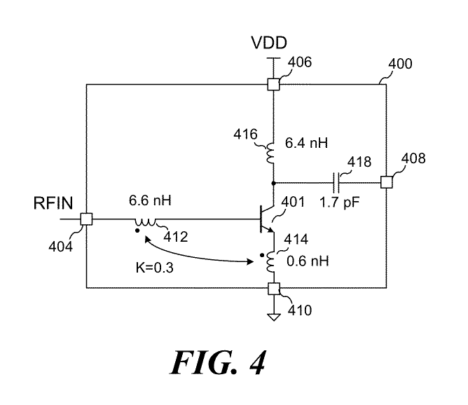

FIG. 4 illustrates LNA integrated circuit 400 according to an embodiment of the present invention. In an embodiment, integrated circuit 400 has transistor 401; input inductor 412 having a value of about 6.6 nH coupled between RF input pin 404 and the base of transistor 401; emitter degeneration inductor 414 coupled between the emitter of transistor 401 and reference pin 410; and output inductor 416 coupled between the collector of transistor 401 and power supply pin 406. Inductor 412 may be transformer coupled to inductor 414 using a spiral inductor structure, such as the structure illustrated in FIG. 2b, and RF output pin 408 is coupled to the collector of transistor 401 via capacitor 418 having a value of about 1.7 pF. Alternatively, other component values may be used besides those shown in accordance with a particular systems's requirements and specifications.

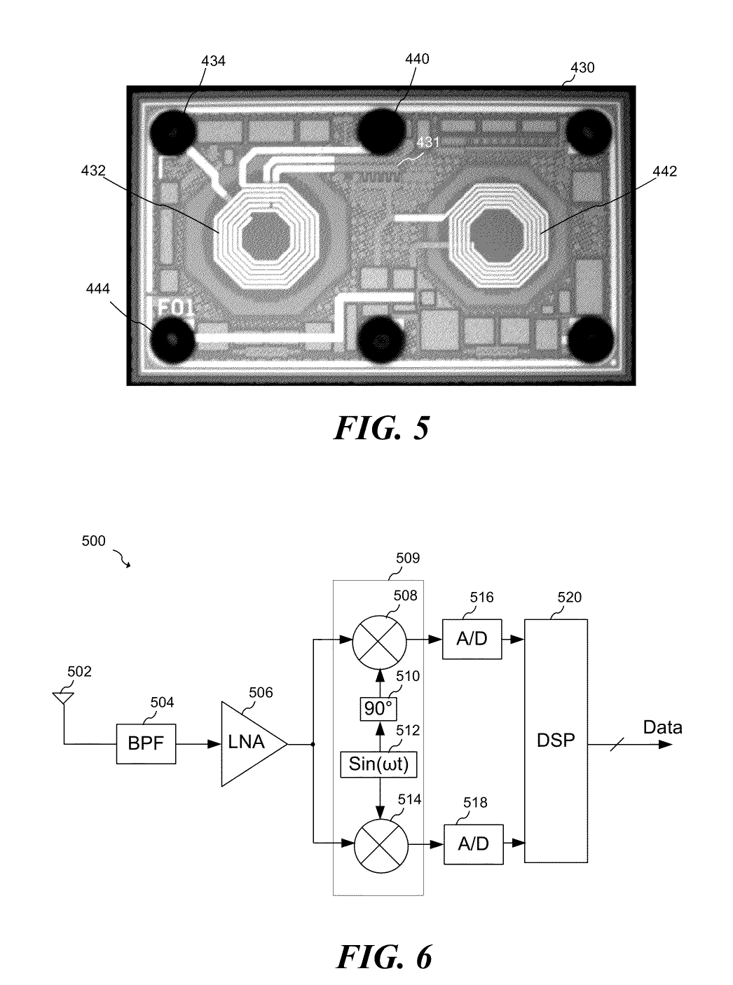

FIG. 5 illustrates a physical layout implementation of embodiment LNA integrated circuit 400. Integrated circuit 430 has transistor 431, transformer 432, and RF choke 442. The RF input is introduced at bump bond pin 440; the ground connection to the emitter degeneration inductance is made at bump bond pin 434 and, the RF output is output at bump bond pin 444. As shown, the inner portion of transformer winding 432 is forms the degeneration inductor, and the outer portion of transformer winding 432 forms the base inductor. It should be understood that the die photo represented in FIG. 5 is just one example of many possible embodiments of the present invention. In alternative embodiments, different device dimensions, different transformer configurations, and different device sizes may be used. Moreover, other bonding types may be used besides bump bonds.

FIG. 6 illustrates example RF signal path 500 that may incorporate embodiment LNA 506. This example RF signal path may be included for example in the front end of the radio receiver that may be found, for example, in a GPS receiver, mobile handset receiver, or other receiver. It should be appreciated that example RF signal path 500 is just one example of many possible receiver implementations.

RF signal path 500 includes antenna 502, a bandpass filter 504, embodiment low noise amplifier 506, quadrature mixer 509, A/D converters 516 and 518, and digital signal processor 520. In an embodiment, a bandpass filter 504 may be implemented using a ceramic filter, a surface acoustic wave (SAW) filter, or other type of filter. By providing a good input match at LNA 506 using embodiment techniques, an adequate match for band pass filter 504 may be ensured. Quadrature mixer 509 includes mixer 508 for the in phase channel, and mixer 514 for the quadrature channel. A signal source, such as an oscillator is represented by sine function 512, and a 90° phase shift is represented by phase shift 510. It should be appreciated, however, that circuits known in the art may be used to implement quadrature mixer 509. With respect to oscillator generation, the LO inputs to mixers 508 and 514 may be generated using circuits such as, but not limited to as an oscillator, a phase locked loop, a polyphase filter, and/or a digital divider. The outputs of quadrature mixer 509 may be converted to the digital domain using A/D converters 516 and 518, the outputs of which may be input into digital signal processor 500. In embodiments, digital signal processor 520 may implement data recovery algorithms known in the art to support a variety of telecommunications and navigation standards such as GSM, CDMA, LTE, GPS, etc. While the embodiment of FIG. 6 illustrates a single conversion system, other RF signal path architectures may be used, for example, dual conversion, triple conversion, Low IF, etc.

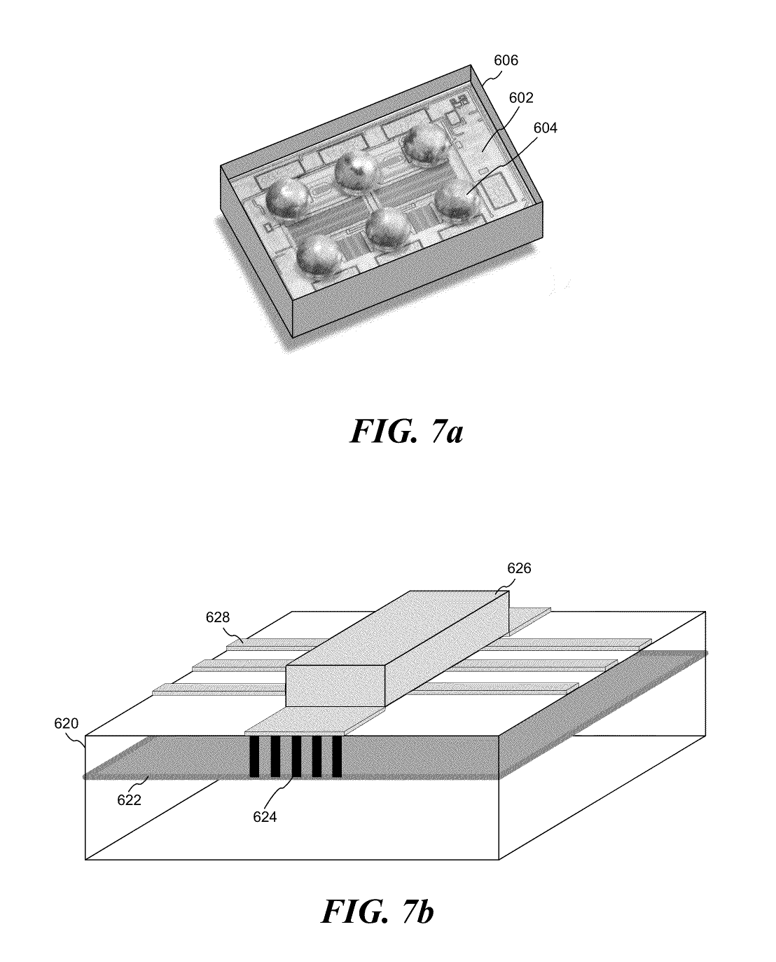

FIG. 7a illustrates embodiment LNA integrated circuit 602, the bottom surface and sides of which are wrapped by conductive shielding layer 606. In an embodiment, shielding layer 606 may be made of foil or other conductive material. In some embodiments, all sides of integrated circuit 602 except for the top surface may be covered by conductive shielding layer 606. As shown, the top surface of LNA integrated circuit 602 has solder bump bonds 604 disposed thereon. Alternatively, portions of the top surface may be fully or partially covered by conductive material 606. In some embodiments, conductive shielding layer 606 provides electromagnetic shielding that extends to embodiment on-chip inductors and transformers.

FIG. 7b illustrates embodiment shielded LNA integrated circuit 626 mounted on printed circuit board (PCB) 620. In an embodiment, solder bump bonds 604 (FIG. 7a) may be used to connect chip pads to pads on PCB 620. Furthermore, PCB ground metal plane 622 may be used to complete the front side shielding of LNA integrated circuit 602 (FIG. 7a), while simultaneously allowing the routing to the PCB pads. The shielding layer of shielded LNA integrated circuit 626 may be connected to PCB ground plane 622 through PCB vias 624. Input, output, bias and power supply signals may be coupled to metal lines 628. It should be understood the shielded LNA integrated circuit embodiments illustrated in FIGS. 7a-b are just examples of many possible embodiment implementations.

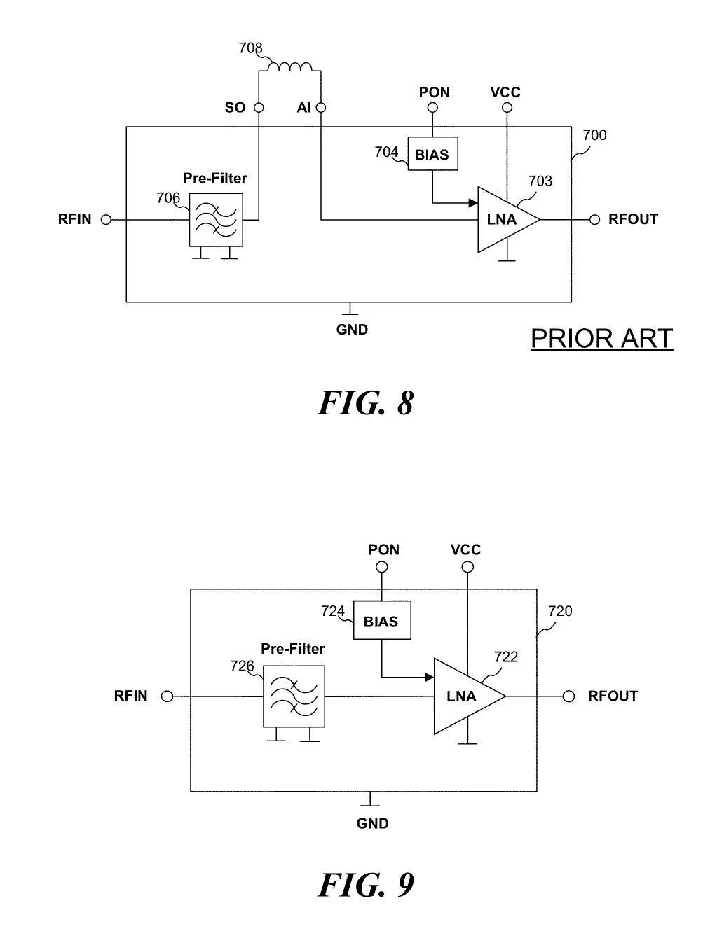

FIG. 8 illustrates a conventional shielded LNA module 700 having pre-filter 706, bias block 704 and LNA circuit 703. Pins SO and AI interface to external inductor 708, which is used to match pre-filter 706 to the input of LNA 703. Signal pin PON is an enable signal coupled to bias block 704, pin RFIN is the RF input, and pin RFOUT is the RF output to shielded LNA module 700. Pin VCC supplies LNA circuit 703 with power.

FIG. 9 illustrates embodiment shielded LNA module 720 having pre-filter 726, bias block 724 and embodiment LNA 722 that includes on-chip matching inductors as described in embodiments above. By using embodiment on-chip transformer-based inductors, the external matching inductor may be eliminated, thereby saving two external pins.

The circuit design of embodiment LNAs may be achieved using iterative design techniques, where the noise performance and input match are simultaneously optimized. In some embodiments, 2.5 dimensional or three-dimensional EM simulations may be used to characterize the performance of on-chip inductors and transformers.

In accordance with an embodiment, a low noise amplifier (LNA) includes a transistor, and a transformer having a first winding coupled between a LNA input terminal and a control node of the transistor, and a second winding magnetically coupled to the first winding coupled between a reference node of the transistor and a LNA reference terminal. An output of the LNA is coupled to an output node of the transistor.

In an embodiment, the transistor is implemented using a bipolar junction transistor (BJT). In such a case, the control node of the transistor is a base of the BJT, the reference node of the transistor is an emitter of the BJT, and the output node of the transistor is a collector of the BJT. In a further embodiment, the transistor is implemented using a metal-oxide field effect transistor (MOSFET). In such a case, the control node of the transistor is a gate of the MOSFET, the reference node of the transistor is a source of the MOSFET, and the output node of the transistor is a drain of the MOSFET.

The LNA may further include an inductor coupled between a LNA power supply terminal and the output node of the transistor. In some embodiments, the transistor and the transformer are disposed on an integrated circuit, and the LNA reference terminal and the LNA input terminal are coupled to output pads of integrated circuit. In an embodiment, the output pads are further coupled to bump bond connections.

In an embodiment, the first winding is implemented using a first integrated inductor, and the second winding is implemented using a second integrated inductor. The first integrated inductor may include a first spiral inductor, and the second integrated inductor may include a second spiral inductor. In some embodiments, the first spiral inductor and the second spiral inductor are disposed on a same metal layer, and magnetic coupling between the first spiral inductor and the second spiral inductor comprises horizontal coupling.

In accordance with a further embodiment, an integrated circuit includes a semiconductor substrate, a transistor disposed on the semiconductor substrate, and a transformer disposed on the semiconductor substrate. The transformer includes a first winding coupled between an input pad and a control node of the transistor, and a second winding magnetically coupled to the first winding coupled between a reference node of the transistor and a reference pad. The output pad is coupled to an output node of the transistor. The input pad and the reference pad may be coupled to bump bond connections. Moreover, the transistor and the transformer may form a low noise amplifier (LNA).

In an embodiment, the transistor of the integrated circuit is implemented using a bipolar junction transistor (BJT). In such a case, the control node of the transistor is a base of the BJT, the reference node of the transistor is an emitter of the BJT, and the output node of the transistor is a collector of the BJT. In a further embodiment, the transistor of the integrated circuit is implemented using a metal-oxide field effect transistor (MOSFET). In such a case, the control node of the transistor is a gate of the MOSFET, the reference node of the transistor is a source of the MOSFET, and the output node of the transistor is a drain of the MOSFET.

In an embodiment, the first winding comprises a first spiral inductor, and the second winding comprises a second spiral inductor, and the first and second spiral inductors disposed on the semiconductor substrate. In some embodiments, the first spiral inductor and the second spiral inductor are disposed on a same metal layer, and magnetic coupling between the first spiral inductor and the second spiral inductor includes horizontal coupling.

In accordance with a further embodiment, a method of operating a low noise amplifier (LNA) comprising a transistor and a transformer disposed on an integrated circuit includes coupling an input signal to a control node of the transistor via a first winding of the transformer, coupling a reference voltage at a reference node of the transistor via a second winding of the transformer, and receiving an output signal from the LNA via an output node of the transistor.

In some embodiments, coupling the input signal to the control node of the transistor includes coupling the input signal to a base of a bipolar junction transistor (BJT), coupling the reference voltage at the reference node of the transistor includes coupling the reference voltage to an emitter of the BJT, and receiving the output signal from the LNA via an output node of the transistor includes receiving the output signal from a collector of the BJT.

In an embodiment, coupling an input signal to the control node of the transistor via a first winding of the transformer includes coupling the input signal via a first spiral inductor, and coupling a reference voltage at the reference node of the transistor via a second winding of the transformer includes coupling the reference voltage via a second spiral inductor horizontally coupled to the first spiral inductor.

In accordance with a further embodiment, a module includes a low noise amplifier (LNA) integrated circuit having a semiconductor substrate, a transistor disposed on the semiconductor substrate, and a transformer disposed on the semiconductor substrate. The transformer may include a first winding coupled between a LNA input pad and a control node of the transistor, and a second winding magnetically coupled to the first winding coupled between a reference node of the transistor and a LNA reference pad. The LNA output pad may be coupled to an output node of the transistor.

In some embodiments, the module further includes a filter coupled between a module input pad and the LNA input pad via an internal module connection. The internal module connection may not be coupled to a component external to the module in some embodiments. A shielding layer may be disposed on at least one surface of the LNA integrated circuit.

Advantages of embodiment systems and methods include the ability to implement a monolithic LNA with an on-chip input-port power match having a low noise figure, using area efficient on-chip inductors. By magnetically coupling the two on-chip inductors, less chip area is needed for their implementation. Furthermore, the overall quality factor of the total implemented inductance may be increased, which translates into improved noise performance. By using on-chip inductors to match the LNA input port, less board space may be needed for the application. Moreover, exposure to external interference that would be otherwise coupled to the circuit via an external matching inductor is reduced. Embodiments in which the LNA package includes electromagnetic shielding have the further advantage of naturally extending the scope of this shielding to the matching inductor.

Embodiment modules that include a pre-filter and LNA have a further advantage of a reduced pin count. Because embodiment on-chip transformer-based inductors are used to match the input of the LNA, the use of an external matching inductor may be avoided. Therefore, two additional pins are not required to interface to an external inductor.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A low noise amplifier (LNA) comprising:
a transistor; and
a transformer comprising a first winding coupled between a LNA input terminal and a control node of the transistor, and a second winding magnetically coupled to the first winding coupled between a reference node of the transistor and a LNA reference terminal, wherein an output of the LNA is coupled to an output node of the transistor.

2. The LNA of claim 1, wherein:
the transistor comprises a bipolar junction transistor (BJT);
the control node of the transistor comprises a base of the BJT;
the reference node of the transistor comprises an emitter of the BJT; and
the output node of the transistor comprises a collector of the BJT.

3. The LNA of claim 1, wherein:
the transistor comprises a metal-oxide field effect transistor (MOSFET);
the control node of the transistor comprises a gate of the MOSFET;
the reference node of the transistor comprises a source of the MOSFET; and
the output node of the transistor comprises a drain of the MOSFET.

4. The LNA of claim 1, further comprising an inductor coupled between a LNA power supply terminal and the output node of the transistor.

5. The LNA of claim 1, wherein the transistor and the transformer are disposed on an integrated circuit.

6. The LNA of claim 5, wherein the LNA reference terminal and the LNA input terminal are coupled to output pads of integrated circuit.

7. The LNA of claim 6, wherein the output pads are further coupled to bump bond connections.

8. The LNA of claim 5, wherein the first winding comprises a first integrated inductor, and the second winding comprises a second integrated inductor.

9. The LNA of claim 8, wherein the first integrated inductor comprises a first spiral inductor, and the second integrated inductor comprises a second spiral inductor.

10. The LNA of claim 9, wherein:
the first spiral inductor and the second spiral inductor are disposed on a same metal layer; and
magnetic coupling between the first spiral inductor and the second spiral inductor comprises horizontal coupling.

11. An integrated circuit comprising:
a semiconductor substrate;
a transistor disposed on the semiconductor substrate; and
a transformer disposed on the semiconductor substrate, the transformer comprising a first winding coupled between an input pad and a control node of the transistor, and a second winding magnetically coupled to the first winding coupled between a reference node of the transistor and a reference pad, wherein an output pad is coupled to an output node of the transistor.

12. The integrated circuit of claim 11, wherein:
the transistor comprises a bipolar junction transistor (BJT) disposed on the semiconductor substrate;
the control node of the transistor comprises a base of the BJT;
the reference node of the transistor comprises an emitter of the BJT; and
the output node of the transistor comprises a collector of the BJT.

13. The integrated circuit of claim 11, wherein:
the transistor comprises a metal-oxide field effect transistor (MOSFET) disposed on the semiconductor substrate;
the control node of the transistor comprises a gate of the MOSFET;
the reference node of the transistor comprises a source of the MOSFET; and
the output node of the transistor comprises a drain of the MOSFET.

14. The integrated circuit of claim 11, wherein the transistor and the transformer form a low noise amplifier (LNA).

15. The integrated circuit of claim 11, wherein the input pad and the reference pad are coupled to bump bond connections.

16. The integrated circuit of claim 11, wherein the first winding comprises a first spiral inductor, and the second winding comprises a second spiral inductor, the first and second spiral inductors disposed on the semiconductor substrate.

17. The integrated circuit of claim 16, wherein:
the first spiral inductor and the second spiral inductor are disposed on a same metal layer; and
magnetic coupling between the first spiral inductor and the second spiral inductor comprises horizontal coupling.

18. A method of operating a low noise amplifier (LNA) comprising a transistor and a transformer disposed on an integrated circuit, the method comprising:
coupling an input signal to a control node of the transistor via a first winding of the transformer;
coupling a reference voltage at a reference node of the transistor via a second winding of the transformer; and
receiving an output signal from the LNA via an output node of the transistor.

19. The method of claim 18, wherein:
coupling the input signal to the control node of the transistor comprises coupling the input signal to a base of a bipolar junction transistor (BJT);
coupling the reference voltage at the reference node of the transistor comprises coupling the reference voltage to an emitter of the BJT; and
receiving the output signal from the LNA via an output node of the transistor comprises receiving the output signal from a collector of the BJT.

20. The method of claim 19, wherein
coupling an input signal to the control node of the transistor via a first winding of the transformer comprising coupling the input signal via a first spiral inductor; and
coupling a reference voltage at the reference node of the transistor via a second winding of the transformer comprises coupling the reference voltage via a second spiral inductor horizontally coupled to the first spiral inductor.

21. A module comprising:
a low noise amplifier (LNA) integrated circuit comprising
a semiconductor substrate,
a transistor disposed on the semiconductor substrate, and
a transformer disposed on the semiconductor substrate, the transformer comprising a first winding coupled between a LNA input pad and a control node of the transistor, and a second winding magnetically coupled to the first winding coupled between a reference node of the transistor and a LNA reference pad, wherein an LNA output pad is coupled to an output node of the transistor.

22. The module of claim 21, further comprising a filter coupled between a module input pad and the LNA input pad via an internal module connection.

23. The module of claim 22, wherein the internal module connection is not coupled to a component external to the module.

24. The module of claim 22, further comprising a shielding layer disposed on at least one surface of the LNA integrated circuit.
